(19) United States
(12) Patent Application Publication
(10) Pub. No.: US 2010/0033204 A1
(43) Pub. Date: Feb. 11, 2010

(54) SEMICONDUCTOR INSPECTION APPARATUS AND SEMICONDUCTOR INTEGRATED CIRCUIT

(76) Inventor: Takeshi Santo, Osaka (JP)

Correspondence Address: WENDEROTH, LIND & PONACK L.L.P., 1030 15th Street, N.W., Suite 400 East, Washington, DC, 20005-1503, US

(21) Appl. No.: 12/442,768

(22) PCT Filed: Sep. 19, 2007
(86) PCT No.: PCT/JP2007/068118

§ 371 Date: Mar. 25, 2009

(30) Foreign Application Priority Data
Sep. 26, 2006 (JP) 2006-261375

(51) Int. Cl. G01R 31/26

(52) U.S. Cl. 324/765

(57) ABSTRACT

In a wafer-level burn-in test, a sufficient power supply current must be supplied to operate semiconductor integrated circuits on a wafer, but the power supply current sometimes exceeds an allowable current level due to such as variations in transistor characteristics of the semiconductor integrated circuits. An operation power supply current at the burn-in test is measured by a current measurement device (3), and an operation frequency of an operation signal (13) supplied to the test target semiconductor integrated circuits is controlled by a signal generation circuit (5) on the basis of the measured current value, thereby controlling the operation power supply current.

### TECHNICAL FIELD

The present invention relates to a semiconductor inspection apparatus and a semiconductor integrated circuit, and more particularly, to a semiconductor inspection apparatus which performs a wafer-level burn-in test on semiconductor integrated circuits.

### BACKGROUND ART

With the increase in scale and integration density of semiconductor integrated circuits, high precision of tests for the semiconductor integrated circuits has increasingly been required. Further, it is becoming indispensable to sort out semiconductor integrated circuits which are likely to cause initial failures by performing an acceleration test during a mass-production test, from the viewpoint of securing the reliability of the semiconductor integrated circuits against miniaturization of semiconductor manufacturing process techniques or complexity due to introduction of semiconductor process techniques which can consolidate analog circuits, memories such as DRAMs (random read/write memories which require memory holding operation), and logic circuits. On the other hand, reduction in procedure upon mass-production shipment is indispensable to meet the demand for cost reduction of the semiconductor integrated circuits.

In the mass-production test for the semiconductor integrated circuits, generally, a prober inspection is executed in the wafer state, and the products that pass the prober inspection are subjected to an acceleration test called a burn-in test, and further, the products that pass the burn-in test are subjected to a final inspection or a shipment inspection to be shipped from the factory.

The burn-in test is an acceleration test in which failures are induced in semiconductor integrated circuits having potentials of generating initial failures by inputting a test signal which makes internal logic circuits efficiently operate under the state where a voltage higher than a power supply voltage for ordinary use is applied, and the failures are detected by performing an inspection during or after the burn-in test, thereby to prevent the semiconductor integrated circuits having potentials of generating initial failures from being shipped out of the factory.

The burn-in test includes a package burn-in test which is executed in the state where semiconductor chips judged as non-defectives in the prober inspection are sealed (packaged), and a wafer-level burn-in test which is executed in the wafer state on which a plurality of semiconductor integrated circuits are mounted.

While the wafer-level burn-in test is performed collectively and simultaneously to the semiconductor integrated circuits mounted on the wafer, supply of a sufficient power supply current is required to operate the semiconductor integrated circuits on the wafer. Accordingly, the semiconductor integrated circuits are usually designed so as to perform the burn-in test operation such that the operation current at the wafer-level burn-in test falls within the power supply capacity which is allowed by the power supply device of the wafer-level burn-in test apparatus performing the wafer-level burn-in test.

Further, when it is previously known that the operation current at the burn-in test would exceed the power supply capacity which is allowed by the power supply device of the wafer-level burn-in apparatus if the designed semiconductor integrated circuits are collectively and simultaneously subjected to the burn-in test, the circuit configurations of the plural semiconductor integrated circuits on the wafer are made different from each other to shift the operation timings of the plural semiconductor integrated circuits from each other in order to limit the operation current within the power supply capacity which is allowed by the power supply device of the wafer-level burn-in test apparatus as disclosed in Patent Document 1.

Patent Document 1: Japanese Published Patent Application No. Hei. 11-121557 (Page 12, FIG. 1)

### DISCLOSURE OF THE INVENTION

### Problems to be Solved by the Invention

As described above, in the wafer-level burn-in test, supply of a sufficient power supply current is required to operate the semiconductor integrated circuits on the wafer, and the semiconductor integrated circuits are usually designed so as to perform the burn-in test operation such that the operation current at the wafer-level burn-in test falls within the power supply capacity which is allowed by the power supply device in the wafer-level burn-in test apparatus performing the wafer-level burn-in test.

However, the power supply current is increased due to that the transistor threshold value (Vt) is reduced by the recent miniaturization of the semiconductor manufacturing process techniques and thereby the off leak current at a high temperature for the burn-in test is significantly increased. Further, a semiconductor integrated circuit in which an analog circuit occupies a larger area relative to the conventional one has been developed, and the power supply current is increased due to an increase in the stationary current of the analog circuit during the burn-in test. In order to perform the wafer-level burn-in test on the semiconductor integrated circuits having such large power supply current, it is proposed in Patent Document 1 to shift the operation timings of the plural semiconductor integrated circuits from each other by making the circuit configurations of the plural semiconductor integrated circuits on the wafer different from each other. In this case, however, the design might be complicated because the circuit configurations of the plural semiconductor integrated circuits are made different from each other.

When the transistor threshold value (Vt) becomes lower than the standard value due to variations in the semiconductor manufacturing processes, the off leak current is further increased, and thereby the operation current might not fall within the power supply capacity which is allowed by the power supply device of the wafer-level burn-in test apparatus, while a sufficient power supply current can be supplied at the standard value. Further, although the semiconductor integrated circuits are usually designed so as to perform the burn-in test operation such that the operation current falls within the power supply capacity which is allowed by the power supply device of the wafer-level burn-in test apparatus, there may arise cases where a difference occurs between the estimation upon design and the actually required power supply capacity, and the operation current at the burn-in test does not fall within the power supply capacity which is allowed by the power supply device of the wafer-level burn-in test apparatus. When the operation current at the burn-in test exceeds the power supply capacity which is allowed by the power supply device of the wafer-level burn-in test apparatus, the power supply device interrupts the supply of power to halt the burn-in test.

The present invention is made to solve the above-described problems and has for its object to provide a semiconductor inspection apparatus and semiconductor integrated circuits, which enable a burn-in test even when the operation current at the burn-in test is increased due to such as a reduction of the transistor threshold value (Vt) below the standard value.

### Measures to Solve the Problem

In order to solve the above-described problems, according to the present invention (claim 1), there is provided a semiconductor inspection apparatus which performs a burn-in test on a plurality of semiconductor integrated circuits which are mounted on a wafer, wherein the operation power supply current obtained at the burn-in test can be controlled.

Further, according to the present invention (claim 2), in the semiconductor inspection apparatus defined in claim 1, the operation power supply current at the burn-in test is measured, and the operation power supply current at the burn-in test is controlled based on the measured value.

Further, according to the present invention (claim 3), in the semiconductor inspection apparatus defined in claim 1 or 2, the control of the operation power supply current at the burn-in test is performed by controlling the operation frequency of the test target semiconductor integrated circuits in the burn-in test.

Further, according to the present invention (claim 4), in the semiconductor inspection apparatus defined in claim 1 or 2, the wafer on which the plural test target semiconductor integrated circuits are mounted is divided into plural test target regions, and the plural test target regions can be time-divisionally operated in the burn-in test.

Further, according to the present invention (claim 5), in the semiconductor inspection apparatus defined in claim 4, each of the plural test target semiconductor integrated circuits is operated with each of plural operation frequencies lower than a predetermined operation frequency, to obtain respective power supply current characteristics of the respective semiconductor integrated circuits from the measured plural current values; and the operation current values of the plural test target semiconductor integrated circuits at the predetermined operation frequency are calculated based on the obtained respective power supply current characteristics, thereby to time-divisionally operate the plural test target regions when the total of the calculated current values is equal to or larger than a predetermined value.

Further, according to the present invention (claim 6), in the semiconductor inspection apparatus defined in claim 4 or 5, the plural test target regions are time-divisionally operated while controlling the presence/absence of power sources which are supplied to the plural test target regions, respectively.

Further, according to the present invention (claim 7), in the semiconductor inspection apparatus defined in claim 4 or 5, the plural test target regions are time-divisionally operated with controlling the presence/absence of an operation signal which is supplied to the semiconductor integrated circuits, respectively, in the plural test target regions.

Further, according to the present invention (claim 8), there is provided a semiconductor inspection apparatus which performs a burn-in test on a plurality of semiconductor integrated circuits which are mounted on a wafer, each of said semiconductor integrated circuits having plural function blocks and being capable of selecting each function block under being operated or under being non-operated, wherein different control signals are applied to said respective function blocks in each of said semiconductor integrated circuits in the burn-in test thereby to time-divisionally operate the plural function blocks.

Further, according to the present invention (claim 9), there is provided a semiconductor integrated circuit which is subjected to a burn-in test, the semiconductor integrated circuit being one among a plurality of semiconductor integrated circuits mounted on a wafer together while said burn-in test is performed, wherein mutually different control signals are applied to respective function blocks possessed by each of said plural semiconductor integrated circuits to time-divisionally operate said plural function blocks, thereby performing a time-division burn-in operation.

### EFFECTS OF THE INVENTION

Since the semiconductor inspection apparatus of the present invention is constructed as described above, even when the operation current at the burn-in test is increased due to such as a reduction in the transistor threshold value (Vt) below the standard value, the burn-in test can be realized by controlling the burn-in operation current so as to be within an allowable range of the wafer-level burn-in test apparatus.

### BRIEF DESCRIPTION OF THE DRAWINGS

FIG. 1 is a diagram illustrating the configuration of a semiconductor inspection apparatus according to a first embodiment of the present invention.

FIG. 2 is a diagram for explaining the operation of controlling the power supply current value in the semiconductor inspection apparatus of the first embodiment.

FIG. 3 is a diagram illustrating the configuration of a semiconductor inspection apparatus according to a second embodiment of the present invention.

FIG. 4 is a diagram illustrating the configuration of a semiconductor inspection apparatus according to a third embodiment of the present invention.

FIG. 5 is a diagram illustrating the configurations of a semiconductor inspection apparatus and semiconductor integrated circuits according to a fourth embodiment of the present invention.

FIG. 6 is a diagram for explaining the operation of controlling the power supply current amounts in the semiconductor inspection apparatuses of the second to fourth embodiments.

### DESCRIPTION OF REFERENCE NUMERALS

100,200,300,400 . . . wafer-level burn-in apparatus
2,2b . . . power supply device
3 . . . current measurement device
4 . . . operation frequency control device
5,5b,5c . . . signal generation device
6 . . . burn-in prober
7 . . . wafer on which test target semiconductor integrated circuits are mounted
7a . . . region A of wafer 7 on which test target semiconductor integrated circuits are mounted
7b . . . region b of wafer 7 on which test target semiconductor integrated circuits are mounted
8 . . . test target semiconductor integrated circuits mounted on wafer 7
8a . . . function block A in test target semiconductor integrated circuit 8
8b . . . function block B in test target semiconductor integrated circuit 8
10,21,24,31 . . . control signal
11 . . . control signal from operation frequency control device 4 to signal generation device 5
12 . . . power supply line for supplying power from power supply device 2 to burn-in prober 6
13 . . . signal line for supplying operation signal from signal generation device 5 to burn-in prober 6
13a . . . signal line for supplying power to region A of wafer 7
13b . . . signal line for supplying power to region B of wafer 7
20 . . . power supply control device
22 . . . control signal from power supply control device 20 to power supply device 2
23 . . . signal generation control device
25 . . . control signal from signal generation control device 23 to signal generation device 5
30 . . . semiconductor integrated circuit block operation control device
32 . . . signal line for supplying semiconductor integrated circuit block operation control signal
32a . . . signal line for supplying control signal to function block A
32b . . . signal line for supplying control signal to function block B
33 . . . control signal from semiconductor integrated circuit block operation control device 30 to signal generation device 5

### BEST MODES TO EXECUTE THE INVENTION

### Embodiment 1

Hereinafter, a semiconductor inspection apparatus according to a first embodiment of the present invention will be described.

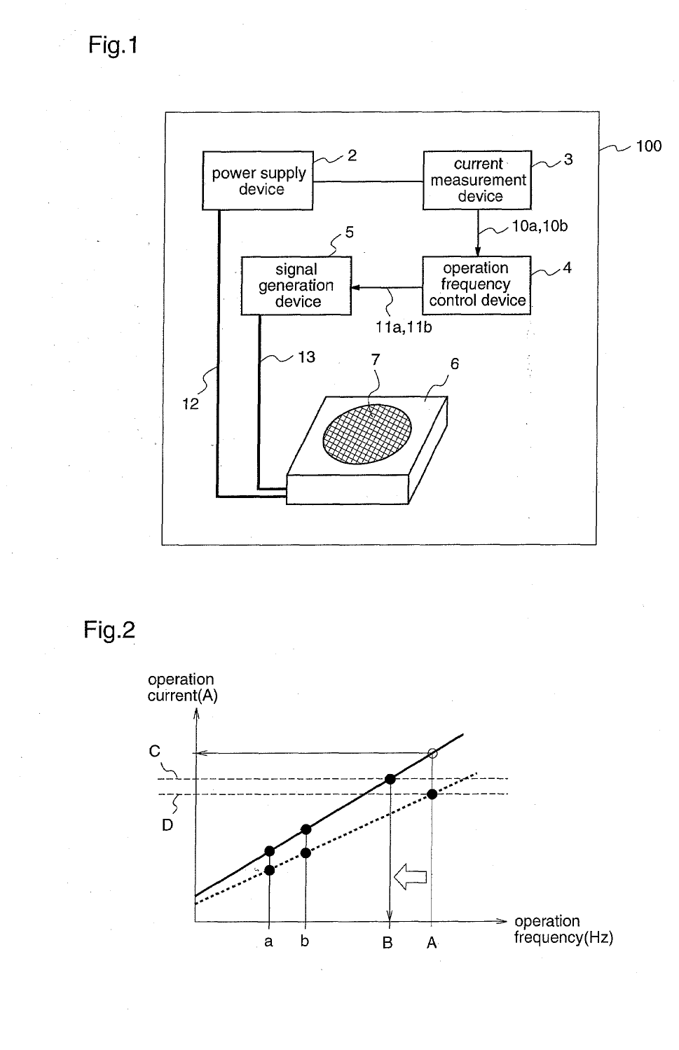

FIG. 1 is a diagram illustrating the configuration of a wafer-level burn-in apparatus as a semiconductor inspection apparatus of the first embodiment. In FIG. 1, reference numeral 100 denotes a wafer-level burn-in apparatus, 2 denotes a power supply device which supplies an operation power to semiconductor integrated circuits as test targets, 3 denotes a current measurement device which measures the value of current supplied to the test target semiconductor integrated circuits, 4 denotes an operation frequency control device which controls the operation frequency of the test target semiconductor integrated circuits on the basis of the measurement result of the current measurement device 3, 5 denotes a signal generation device which supplies an operation signal to the test target semiconductor integrated circuits, 6 denotes a burn-in prober which is an inspection jig for supplying the operation power and the operation signal to a wafer on which the test target semiconductor integrated circuits are mounted, 7 denotes the wafer on which the test target semiconductor integrated circuits are mounted, 10 denotes a control signal which is transferred from the current measurement device 3 to the operation frequency control device 4, 11 denotes a control signal with which the operation frequency control device 4 controls the signal generation device 5, 12 denotes a power supply line for supplying the operation power from the power supply device 2 through the burn-in prober 6 to the test target semiconductor integrated circuits, and 13 denotes a signal line for supplying the operation signal from the signal generation device 5 through the burn-in prober 6 to the test target semiconductor integrated circuits.

Next, the operation of the wafer-level burn-in apparatus 100 of this first embodiment will be described with reference to FIGS. 1 and 2.

In FIG. 1, the wafer 7 on which a plurality of test target semiconductor integrated circuits are mounted is fixed by the burn-in prober 6, and the power supply line 12 and the signal line 13 are electrically connected to the respective test target semiconductor integrated circuits mounted on the wafer 7, and thereby the power for operation and the signal for operation are supplied to the semiconductor integrated circuits.

Although the wafer-level burn-in test is performed by that the power and signal for operation are respectively supplied from the power supply device 2 and the signal generation device 5 in the wafer-level burn-in apparatus 100 to the test target semiconductor integrated circuits, the power supply capacity required for the burn-in test might be varied due to variations in the transistor threshold value (Vt) even under the same operating condition and, in some cases, it does not fall within the power supply capacity which is allowed by the power supply device 2.

Further, although the semiconductor integrated circuits are usually designed to perform the burn-in test operation such that the operation current at the burn-in test falls within the power supply capacity which is allowed by the power supply device 2, there are cases where a difference occurs between the estimation upon the design and the actually required power supply capacity and thereby the operation current at the burn-in test does not fall within the power supply capacity which is allowed by the power supply device 2.

If the operation current at the burn-in test exceeds the power supply capacity which is allowed by the power supply device 2, the power supply device 2 interrupts the supply of power to halt the burn-in test.

In the wafer-level burn-in apparatus 100 of this first embodiment, the operation frequency of the test target semiconductor integrated circuits is controlled so that the operation current at the burn-in test does not exceed the power supply capacity which is allowed by the power supply device.

FIG. 2 is a diagram for explaining the operation of controlling the power supply current amount in the wafer-level burn-in apparatus 100 of this first embodiment. Hereinafter, the specific operation of controlling the power supply current amount in the wafer-level burn-in apparatus 100 of this first embodiment will be described with reference to FIGS. 1 and 2.

In the burn-in test, test parameters for performing product assurance have been decided, and the operation frequency of the test target semiconductor integrated circuits in the burn-in test is usually defined as a test parameter. The wafer-level burn-in apparatus 100 of this first embodiment is operated as follows with an operation frequency other than the test-parameter operation frequency of the test target semiconductor integrated circuits when the wafer-level burn-in test is started.

Initially, an operation signal which makes the plural semiconductor integrated circuits as burn-in test targets on the wafer operate at an operation frequency a which is lower than the operation frequency A as the test parameter is supplied from the signal generation device 5 to the plural semiconductor integrated circuit, and the operation current at this time is measured by the current measurement device 3, and then the measured current value is transferred as a control signal 10a to the operation frequency control device 4.

Next, an operation signal which makes the plural semiconductor integrated circuits as burn-in test targets on the wafer operate at an operation frequency b which is lower than the operation frequency A as the test parameter and is different from the operation frequency a is supplied from the signal generation device 5 to the plural semiconductor integrated circuits, and the operation current at this time is measured by the current measurement device 3, and then the measured current value is transferred as a control signal 10b to the operation frequency control device 4.

The operation frequency control device 4 obtains the power supply current characteristics of the semiconductor integrated circuits as burn-in test targets from the two current values 10a and 10b transferred from the current measurement device 3 and the values of the operation frequencies a and b, and further, calculates an operation current value to be obtained when the plural semiconductor integrated circuits as burn-in test targets are operated with the operation frequency A as the test parameter on the basis of the obtained power supply current characteristics.

When the obtained power supply current characteristics indicate that the calculated operation current value (operation current D) does not exceed the allowable current C of the power supply device 2 as shown by dotted lines in FIG. 2, the operation frequency control device 4 transfers setting information for making the signal generation device 5 output an operation signal which makes the plural semiconductor integrated circuits as burn-in test targets operate at the operation frequency A as the test parameter, as a control signal 11a to the signal generation device 5.

On the other hand, when the obtained power supply current characteristics indicate that the calculated operation current value (white dot in FIG. 2) exceeds the allowable current C of the power supply device 2 as shown by solid lines in FIG. 2, the operation frequency control device 4 transfers setting information as a control signal 11b to the signal generation device 5, which setting information makes the signal generation device 5 output an operation signal which makes the plural semiconductor integrated circuits as burn-in test targets operate at the operation frequency B by which the operation current of the semiconductor integrated circuits falls within the allowable current of the power supply device.

Thereafter, the signal generation device 5 generates an operation signal on the basis of the control signals 11 (11a and 11b) supplied from the operation frequency control device 4, and supplies the operation signal to the test target semiconductor integrated circuits to execute the burn-in test. Thereby, in the wafer-level burn-in apparatus 100 of this first embodiment, the operation current at the burn-in test is prevented from exceeding the allowable current of the power supply device 2, and thus the burn-in test can be reliably carried out even when the operation current at the burn-in test is increased due to such as a reduction in the transistor threshold value (Vt) below the standard value.

As described above, according to the first embodiment, the operation power supply current at the burn-in test is measured, and the operation frequency of the operation signal supplied to the test target semiconductor integrated circuits is controlled based on the measured current value, thereby to control the operation power supply current. Therefore, the burn-in operation current can be controlled so as to be within the allowable range of the wafer-level burn-in test apparatus, and thus effective burn-in test can be performed with reliability.

### Embodiment 2

Hereinafter, a semiconductor inspection apparatus according to a second embodiment of the present invention will be described.

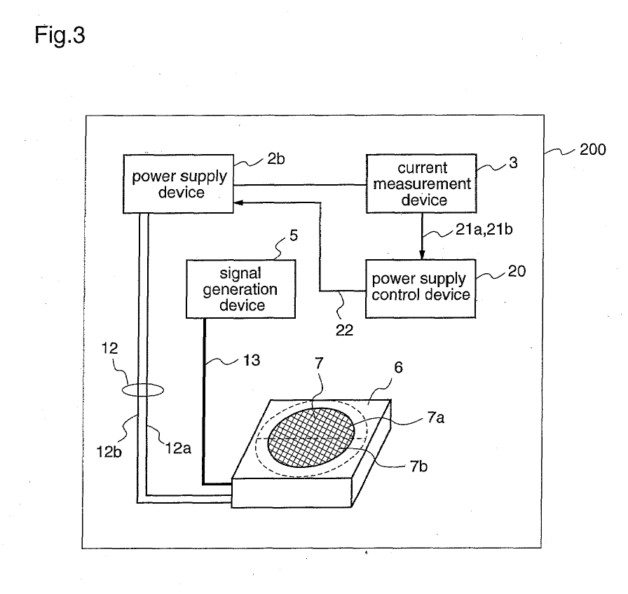

FIG. 3 is a diagram illustrating the configuration of a wafer-level burn-in apparatus as a semiconductor inspection apparatus of the second embodiment. In FIG. 3, reference numeral 200 denotes a wafer-level burn-in apparatus, 2b denotes a power supply device which supplies an operation power to semiconductor integrated circuits as test targets, 3 denotes a current measurement device which measures the value of current supplied to the test target semiconductor integrated circuits, 5 denotes a signal generation device which supplies an operation signal to the test target semiconductor integrated circuits, 6 denotes a burn-in prober which is an inspection jig for supplying the operation power and the operation signal to a wafer on which the test target semiconductor integrated circuits are mounted, 7 denotes the wafer on which the test target semiconductor integrated circuits are mounted, 7a denotes a region A of the wafer 7 on which the test target semiconductor integrated circuits are mounted, 7b denotes a region B of the wafer 7 on which the test target semiconductor integrated circuits are mounted, 12 denotes a power supply line for supplying the operation power from the power supply device 2 through the burn-in prober 6 to the test target semiconductor integrated circuits, 12a denotes a power supply line for supplying the power to the region 7a of the wafer 7 on which the test target semiconductor integrated circuits are mounted, 12b denotes a power supply line for supplying the power to the region 7b of the wafer on which the test target semiconductor integrated circuits are mounted, 13 denotes a signal line for supplying the operation signal from the signal generation device 5 through the burn-in prober 6 to the test target semiconductor integrated circuits, 20 denotes a power supply control device which controls the power supplied to the test target semiconductor integrated circuits on the basis of the measurement result of the current measurement device 3, 21 denotes a control signal transferred from the current measurement device 3 to the power supply control device 20, and 22 denotes a control signal with which the power supply control device 20 controls the power supply device 2b.

Next, the operation of the wafer-level burn-in apparatus 200 of the second embodiment will be described.

The wafer 7 on which the test target semiconductor integrated circuits are mounted is fixed by the burn-in prober 6, and the power supply line 12 and the signal line 13 are electrically connected to the respective test target semiconductor integrated circuits mounted on the wafer to supply the power and signal for operation, respectively.

In the wafer-level burn-in apparatus 200 of this second embodiment, the power supply line-12 which supplies the operation power from the power supply device 2b to the plural test target semiconductor integrated circuits is divided into the power supply lines 12a and 12b, and the power supply line 12a and the power supply line 12b supply the operation power to the semiconductor integrated circuits existing in the region A7a of the wafer 7 and to the semiconductor integrated circuits existing in the region B7b of the wafer 7, respectively.

While the wafer-level burn-in test is performed by that the power and signal for operation are respectively supplied from the power supply device 2b and the signal generation device 5 in the wafer-level burn-in apparatus 200 to the test target semiconductor integrated circuits on the wafer 7, the power supply capacity required for the burn-in test varies with variations in the transistor threshold value (Vt) even under the same operating condition and, in some cases, it does not fall within the power supply capacity which is allowed by the power supply device 2b.

Although the semiconductor integrated circuits are usually designed so as to perform the burn-in test operation such that the operation current at the burn-in test falls within the power supply capacity which is allowed by the power supply device 2b, there are cases where a difference might occur between the estimation upon the design and the actually required power supply capacity and thereby the operation current does not fall within the power supply capacity which is allowed by the power supply device 2b.

If the operation current at the burn-in test exceeds the power supply capacity which is allowed by the power supply device 2b, the power supply device 2b interrupts the supply of power to halt the burn-in test.

In the wafer-level burn-in apparatus 200 of this second embodiment, the in-plane region of the wafer on which the test target semiconductor integrated circuits are mounted is divided into two regions, and the presence/absence of the supply of power to each of the divided regions is controlled so that the operation current at the burn-in test does not exceed the power supply capacity which is allowed by the power supply device 2b.

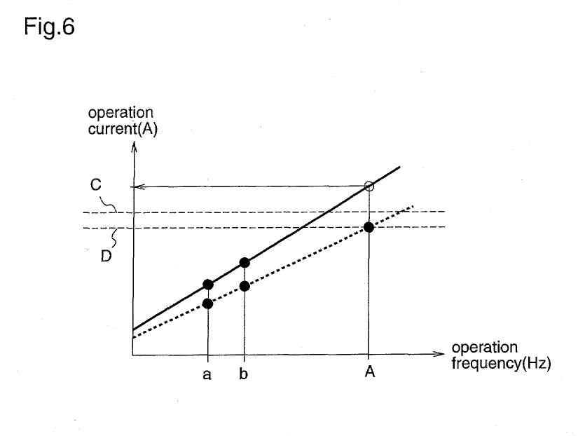

FIG. 6 is a diagram for explaining the operation of controlling the power supply current amount in the wafer-level burn-in apparatus of the second embodiment, and this figure will be used for explaining the operations of third and fourth embodiments that follow. Hereinafter, the detailed operation of controlling the power supply current amount in the wafer-level burn-in apparatus 200 of this second embodiment will be described with reference to FIGS. 3 and 6.

Test parameters for performing product assurance have been determined in the burn-in test, and generally the operation frequency of the test target semiconductor integrated circuits during the burn-in test is also defined as a test parameter. The wafer-level burn-in apparatus 200 of this second embodiment operates as follows with an operation frequency other than the test-parameter operation frequency of the test target semiconductor integrated circuits when the wafer-level burn-in test is started.

Initially, under the state where the power is supplied from the power supply device 2b to the entirety of the wafer 7, i.e., to both the region A7a and region B7b, an operation signal for operating the plural semiconductor integrated circuits as burn-in test targets in the both regions A7a and B7b of the wafer 7 with an operation frequency a that is lower than the operation frequency A as the test parameter is supplied from the signal generation device 5 to the plural semiconductor integrated circuits. Then, the operation current obtained when the plural semiconductor integrated circuits are thus operated is measured by the current measurement device 3, and the measured current value is transferred as a control signal 21a to the power supply control device 20.

Next, under the state where the power is supplied from the power supply device 2b to the entirety of the wafer, an operation signal which makes the plural semiconductor integrated circuits as burn-in test targets operate at an operation frequency b which is lower than the operation frequency A as the test parameter and is different from the operation frequency a is supplied from the signal generation device 5 to the plural semiconductor integrated circuits. Then, the operation current obtained when the plural semiconductor integrated circuits are thus operated is measured by the current measurement device 3, and the measured current is transferred as a control signal 21b to the power supply control device 20.

The power supply control device 20 obtains the power supply current characteristics of the plural semiconductor integrated circuits as burn-in test targets from the two current values 21a and 21b transferred from the current measurement device 3 and the values of the operation frequencies a and b, and calculates an operation current value to be obtained when the plural semiconductor integrated circuits as burn-in test targets are operated with the operation frequency A as the test parameter, on the basis of the obtained power supply current characteristics.

When the obtained power supply current characteristics indicate that the calculated operation current value (operation current D) does not exceed the allowable current C of the power supply device 2b as shown by dotted lines in FIG. 6, the power supply control device 20 controls the power supply device 2b by the control signal 22 so as to keep the state where the power supply current is supplied simultaneously to both the region A7a and the region B7b, and the signal generation device 5 outputs the operation signal which makes the plural test target semiconductor integrated circuits operate at the operation frequency A as the test parameter to the test target semiconductor integrated circuits, thereby executing the burn-in test.

On the other hand, when the obtained power supply current characteristics are such that the calculated operation current value (white dot in FIG. 6) exceeds the allowable current C of the power supply device 2 as shown by a solid line in FIG. 6, the power supply control device 20 controls the power supply device 2b with the control signal 22 so as to supply the power supply current alternately and time-divisionally to the region A7a and the region B7b by alternately turning on and off the respective power supply currents that flow through the power supply lines 12a and 12b, and an operation signal which makes the plural test target semiconductor integrated circuits operate at the operation frequency A as the test parameter is supplied from the signal generation device 5 to the plural test target semiconductor integrated circuits, thereby executing the burn-in test. The interval of the ON/OFF switching between the power supply currents that flow through the power supply lines 12a and 12b may be appropriately set, and for example, it may be every 100 clocks of the operation clocks.

As described above, when the calculated operation current value exceeds the allowable current of the power supply device 2b, the power supply current is alternately and time-divisionally supplied to the region A7a and the region B7b to make the region A7a and the region B7b operate time-divisionally, and thus the operation current that flows at one time can be reduced to prevent the operation current from exceeding the power supply capacity which is allowed by the power supply device 2b. Therefore, in the wafer-level burn-in apparatus 200 of this second embodiment, the operation current at the burn-in test is prevented from exceeding the allowable current of the power supply device 2b, and the burn-in test can be reliably performed even when the operation current at the burn-in test is increased due to such as a reduction in the transistor threshold value (Vt) below the standard value.

As described above, according to the second embodiment, the wafer on which the test target semiconductor integrated circuits are mounted is divided into plural test target regions, and the presence/absence of the power source to be supplied to each of the plural test target regions is controlled during the burn-in test, thereby to enable control for the time-division operation of the plural test target regions. Therefore, the burn-in operation current can be controlled so as to be within the allowable range of the wafer-level burn-in test apparatus, and thus effective burn-in test can be performed with reliability.

In the present invention, the way of judging as to whether the power supply current should be supplied alternately and time-divisionally to the divided plural test target regions or it should be supplied simultaneously to the both regions is not restricted to that described above. For example, the region A7a and the region B7b may be time-divisionally operated when a sum of the measured values of two operation currents exceeds the allowable current of the power supply device, which operation currents are the operation current obtained when the semiconductor integrated circuits are operated with the test-parameter operation frequency while supplying the power supply current to only the region A7a, and the operation current obtained when the semiconductor integrated circuits are operated with the test-parameter operation frequency while supplying the power supply current to only the region B7b.

While in this second embodiment the in-plane area of the wafer on which the test target semiconductor integrated circuits are mounted is divided into two regions, it may be divided into three or more regions.

### Embodiment 3

Hereinafter, a semiconductor inspection apparatus according to a third embodiment of the present invention will be described.

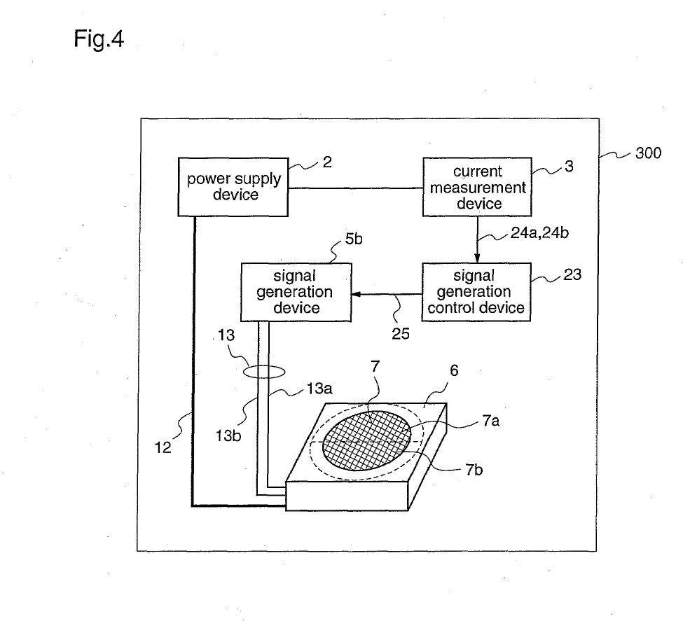

FIG. 4 is a diagram illustrating the configurations of a semiconductor inspection apparatus and semiconductor integrated circuits according to the third embodiment. In FIG. 4, reference numeral 300 denotes a wafer-level burn-in apparatus, 2 denotes a power supply device which supplies an operation power to the test target semiconductor integrated circuits, 3 denotes a current measurement device which measures the value of current supplied from the power supply device 2 to the test target semiconductor integrated circuits, 5b denotes a signal generation device which supplies an operation signal to the test target semiconductor integrated circuits, 6 denotes a burn-in prober which is an inspection jig for supplying the operation power and the operation signal to a wafer on which the test target semiconductor integrated circuits are mounted, 7 denotes the wafer on which the test target semiconductor integrated circuits are mounted, 7a denotes a region A of the wafer 7 on which the test target semiconductor integrated circuits are mounted, 7b denotes a region B of the wafer 7 on which the test target semiconductor integrated circuits are mounted, 12 denotes a power supply line for supplying the operation power from the power supply device 2 of the wafer-level burn-in apparatus 300 through the burn-in prober 6 to the test target semiconductor integrated circuits, 13 denotes a signal line for supplying the operation signal from the signal generation device 5 through the burn-in prober 6 to the test target semiconductor integrated circuits, 13a denotes a signal line for supplying the operation signal to the region A of the wafer 7 on which the test target semiconductor integrated circuits are mounted, 13b denotes a signal line for supplying the operation signal to the region B of the wafer 7 on which the test target semiconductor integrated circuits are mounted, 23 denotes a signal generation control device which controls a test signal supplied to the test target semiconductor integrated circuits on the basis of the measurement result of the current measurement device 3, 24 denotes a control signal transferred from the current measurement device 3 to the signal generation control device 23, and 25 denotes a control signal with which the signal generation control device 23 controls the signal generation device 5b.

Next, the operation of the wafer-level burn-in apparatus 300 of this third embodiment will be described.

The wafer 7 on which the test target semiconductor integrated circuits are mounted is fixed by the burn-in prober 6, and the power supply line 12 and the signal line 13 are electrically connected to the respective test target semiconductor integrated circuits mounted on the wafer 7 to supply the power and signal for operation, respectively.

In the wafer-level burn-in apparatus 300 of this third embodiment, the signal line 13 which supplies the operation signal from the signal generation device 5b to the plural test target semiconductor integrated circuits is divided into signal lines 13a and 13b, and the signal line 13a supplies the operation signal to the semiconductor integrated circuits existing in the region A7a of the wafer 7 while the signal line 13b supplies the operation signal to the semiconductor integrated circuits existing in the region B8b of the wafer 7.

While the wafer-level burn-in test is performed by that the power and signal for operation are respectively supplied from the power supply device 2 and the signal generation device 5 of the wafer-level burn-in apparatus 300 to the test target semiconductor integrated circuits, the power supply capacity required for the burn-in test might be varied at this time due to variations in the transistor threshold value (Vt) even under the same operating condition and, in some cases, it does not fall within the power supply capacity which is allowed by the power supply device 2.

Further, although the semiconductor integrated circuits are usually designed to perform the burn-in test operation such that the operation current at the burn-in test falls within the power supply capacity which is allowed by the power supply device 2, there are cases where a difference occurs between the estimation upon design and the actually required power supply capacity and thereby the operation current at the burn-in test does not fall within the power supply capacity which is allowed by the power supply device 2.

If the operation current at the burn-in test exceeds the power supply capacity which is allowed by the power supply device 2b, the power supply device 2 interrupts the supply of power to halt the burn-in test.

In the wafer-level burn-in apparatus 300 of this third embodiment, the in-plane area of the wafer on which the test target semiconductor integrated circuits are mounted is divided into two regions, and the presence/absence of supply of the operation signal to each of the divided regions is controlled so that the operation current at the burn-in test does not exceed the power supply capacity which is allowed by the power supply device 2b.

Hereinafter, the operation of the wafer-level burn-in apparatus 300 of this third embodiment will be described with reference to FIGS. 4 and 6.

In the burn-in test, test parameters for performing product assurance have been determined, and generally the operation frequency of the test target semiconductor integrated circuits during the burn-in test is also defined as a test parameter. The wafer-level burn-in apparatus 300 of this third embodiment operates as follows with an operation frequency other than the test-parameter operation frequency of the test target semiconductor integrated circuits when the wafer-level burn-in test is started.

Initially, under the state where the power is supplied from the power supply device 2 to the entirety of the wafer 7, i.e., to both of the region A7a and region B7b, an operation signal for operating the plural semiconductor integrated circuits as burn-in test targets in the both regions A7a and B7b of the wafer 7 at an operation frequency a that is lower than the operation frequency A as the test parameter is supplied from the signal generation device 5 to the plural semiconductor integrated circuits. Then, the operation current when the plural semiconductor integrated circuits are thus operated is measured by the current measurement device 3, and the measured current value is transferred as a control signal 24a to the signal generation control device 23.

Next, under the state where the power is supplied from the power supply device 2b to the entirety of the wafer, an operation signal which makes the plural semiconductor integrated circuits as burn-in test targets in the both regions A7a and B7b operate at an operation frequency b which is lower than the operation frequency A as the test parameter and is different from the operation frequency a is supplied from the signal generation device 5 to the plural semiconductor integrated circuits. Then, the operation current when the plural semiconductor integrated circuits are thus operated is measured by the current measurement device 3, and the measured current is transferred as a control signal 24b to the signal generation control device 23.

The signal generation control device 23 obtains the power supply current characteristics of the plural semiconductor integrated circuits as burn-in test targets from the two current values 24a and 24b transferred from the current measurement device 3 and the values of the operation frequencies a and b, and calculates an operation current value to be obtained when the plural semiconductor integrated circuits as burn-in test targets are operated with the operation frequency A as the test parameter on the basis of the obtained power supply current characteristics.

when the obtained power supply current characteristics are such that the calculated operation current value (operation current D) does not exceed the allowable current C of the power supply device 2 as shown by dotted lines in FIG. 6, the signal generation control apparatus 23 controls the signal generation device 5b with the control signal 25 so as to maintain the state where the operation signal for operating the plural semiconductor integrated circuits as burn-in test targets at the operation frequency A as the test parameter is supplied simultaneously to both of the region A7a and the region B7b, and the power supply device 2 supplies the power to the entirety of the wafer 7, thereby executing the burn-in test.

On the other hand, when the obtained power supply current characteristics are such that the calculated operation current value (white dot in FIG. 6) exceeds the allowable current C of the power supply device 2 as shown by a solid line in FIG. 6, the signal generation control device 23 controls the signal generation device 5 by the control signal 25 so as to supply the operation signal which makes the respective semiconductor integrated circuits as burn-in test targets in the regions A7a and B7b operate at the operation frequency A as the test parameter is alternately and time-divisionally supplied to the signal lines 13a and 13b, while the power supply device 2 supplies the power to the entirety of the wafer 7, thereby executing the burn-in test. The interval of switching the operation signals from the signal lines 13a and 13b may be appropriately set, for example, it may be every 100 clocks of the operation clocks.

As described above, when the calculated operation current value exceeds the allowable current of the power supply device 2, the operation signal is supplied alternately and time-divisionally to the region A7a and the region B7b to make the region A7a and the region B7b operate time-divisionally, and thus the operation current that flows at one time can be reduced to prevent the operation current from exceeding the power supply capacity which is allowed by the power supply device 2. Thereby, the burn-in test can be reliably performed even when the operation current at the burn-in test is increased due to such as a reduction in the transistor threshold value (Vt) below the standard value.

As described above, according to the third embodiment, the wafer on which the test target semiconductor integrated circuits are mounted is divided into plural test target regions, and the presence/absence of the operation signal supplied to the semiconductor integrated circuits in each of the plural test target regions is controlled during the burn-in test, thereby to realize control for the time-division operation of the plural test target regions. Therefore, even when the operation current at the burn-in test is increased due to such as a reduction in the transistor threshold value (Vt) below the standard value, the burn-in operation current can be controlled so as to be within the allowable range of the wafer-level burn-in test apparatus, and thus effective burn-in test can be executed with reliability.

In the present invention, the way of judging as to whether the operation signal should be supplied alternately and time-divisionally to the divided plural test target regions or it should be supplied simultaneously to the entire test target regions is not restricted to that described above. For example, the region A7a and the region B7b may be time-divisionally operated when a sum of the measured values of two operation currents exceeds the allowable current of the power supply device, which operation currents are the operation current obtained when the semiconductor integrated circuits are operated with the test-parameter operation frequency while supplying the operation signal to only the region A7a, and the operation current obtained when the semiconductor integrated circuits are operated with the test-parameter operation frequency while supplying the operation signal to only the region B7b.

While in this third embodiment the in-plane region of the wafer on which the test target semiconductor integrated circuits are mounted is divided into two regions, it may be divided into three or more regions.

### Embodiment 4

Hereinafter, a semiconductor inspection apparatus and semiconductor integrated circuits according to a fourth embodiment of the present invention will be described.

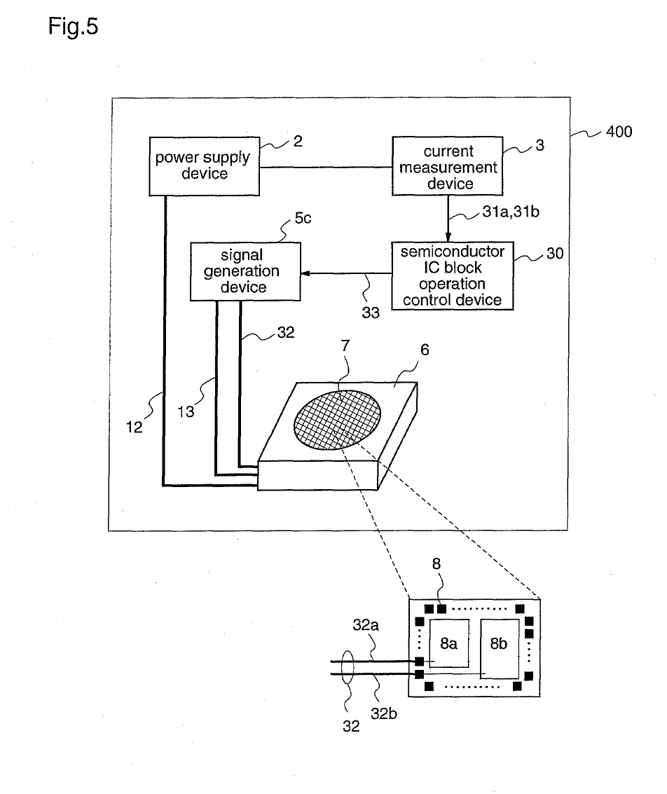

FIG. 5 is a diagram illustrating the configurations of a wafer-level burn-in apparatus as a semiconductor inspection apparatus of this fourth embodiment and semiconductor integrated circuits tested by the wafer-level burn-in apparatus.

In FIG. 5, reference numeral 400 denotes a wafer-level burn-in apparatus, 2 denotes a power supply device which supplies an operation power to the test target semiconductor integrated circuits, 3 denotes a current measurement device which measures the value of current supplied from the power supply device 2 to the test target semiconductor integrated circuits, 5c denotes a signal generation device which supplies an operation signal to the test target semiconductor integrated circuits, 6 denotes a burn-in prober which is an inspection jig for supplying the operation power and the operation signal to a wafer on which the test target semiconductor integrated circuits are mounted, 7 denotes the wafer on which the test target semiconductor integrated circuits are mounted, 8 denotes the test target semiconductor integrated circuits mounted on the wafer 7, 8a denotes a function circuit block A included in each test target semiconductor integrated circuit 8, 8b denotes a function circuit block B included in each test target semiconductor integrated circuit 8, 12 denotes a power supply line for supplying the operation power from the power supply device 2 through the burn-in prober 6 to the test target semiconductor integrated circuits, 13 denotes a signal line for supplying the operation signal from the signal generation device 5 through the burn-in prober 6 to the test target semiconductor integrated circuits, 30 denotes a semiconductor integrated circuit block operation control device which controls the signal generation device 5c, and 31 denotes a control signal transferred from the current measurement device 3 to the semiconductor integrated circuit block operation control device 30. Further, reference numeral 32 denotes a signal line for supplying a semiconductor integrated circuit block operation control signal from the signal generation device 5 to the burn-in prober 6, which includes a signal line 32a for supplying the semiconductor integrated circuit block operation control signal to the function circuit block A in the test target semiconductor integrated circuit 8, and a signal line 32b for supplying the semiconductor integrated circuit block operation control signal to the function circuit block B in the test target semiconductor integrated circuit 8. Reference numeral 33 denotes a control signal with which the semiconductor integrated circuit block operation control device 30 controls the signal generation device 5c.

Each of the semiconductor integrated circuits 8 as wafer-level burn-in test targets is configured such that it has the plural function blocks 8a and 8b as described above, and operation/non-operation of each of the plural function blocks can be selected according to an external control signal.

Next, the operation of the wafer-level burn-in apparatus 400 of this fourth embodiment will be described.

The wafer 7 on which the test target semiconductor integrated circuits are mounted is fixed by the burn-in prober 6, and the power supply line 12 and the signal lines 13 and 32 are electrically connected to the respective test target semiconductor integrated circuits mounted on the wafer 7, thereby supplying the power and signal for operation to the semiconductor integrated circuits.

In the wafer-level burn-in apparatus 400 of this fourth embodiment, the signal line 32 for supplying the semiconductor integrated circuit block operation control signal is divided into the signal lines 32a and 32b, and the signal line 32a supplies the control signal to the function circuit block A8a in the test target semiconductor integrated circuit 8 while the signal line 32b supplies the control signal to the function circuit block B8b in the test target semiconductor integrated circuit 8.

Further, in this fourth embodiment, the control signals 32a and 32b are given by logic values of “0” and “1”, and each of the function circuit blocks 8a and 8b in the semiconductor integrated circuit 8 goes in the operation state when the control signal of the logic value “1” is given while it goes in the non-operation state when the control signal of the logic value “0” is given.

Although the wafer-level burn-in test is performed by that the power and signal for operation are respectively supplied from the power supply device 2 and the signal generation device 5 of the wafer-level burn-in apparatus 400 to the test target semiconductor integrated circuits, the power supply capacity required for the burn-in test might be varied at this time due to variations in the transistor threshold value (Vt) even under the same operating condition and, in some cases, it does not fall within the power supply capacity which is allowed by the power supply device 2.

Further, although the semiconductor integrated circuits are usually designed to perform the burn-in test operation such that the operation current at the burn-in test falls within the power supply capacity which is allowed by the power supply device 2, there are cases where a difference may occur between the estimation upon design and the actually required power supply capacity and thereby the operation current at the burn-in test does not fall within the power supply capacity which is allowed by the power supply device 2.

If the operation current at the burn-in test exceeds the power supply capacity which is allowed by the power supply device 2, the power supply device 2 interrupts the supply of power to halt the burn-in test.

In the wafer-level burn-in apparatus 400 of this fourth embodiment, the signal line 32 which supplies the semiconductor integrated circuit block operation control signal is divided into the signal lines 32a and 32b, and the signal line 32a supplies the control signal to the function circuit block A8a in the test target semiconductor integrated circuit 8 while the signal line 32b supplies the control signal to the function circuit block B8b in the test target semiconductor integrated circuit 8.

Hereinafter, the specific operation of controlling the power supply current amount in the wafer-level burn-in apparatus 400 of this fourth embodiment will be described with reference to FIGS. 5 and 6.

In the burn-in test, test parameters for performing product assurance have been determined, and usually the operation frequency of the test target semiconductor integrated circuits during the burn-in test is also defined as a test parameter. The wafer-level burn-in apparatus 400 of this fourth embodiment operates as follows with an operation frequency other than the test-parameter operation frequency of the test target semiconductor integrated circuits when the wafer-level burn-in test is started.

Initially, both of the control signals 32a and 32b of the semiconductor integrated circuit block operation control signal 32 outputted from the signal generation device 5c are set to the logic value “1”, i.e., both of the function circuits blocks 8a and 8b in the semiconductor integrated circuit 8 are put in their operating states, and an operation signal for operating the plural semiconductor integrated circuits 8 as burn-in test targets on the wafer 7 at an operation frequency a that is lower than the operation frequency A as the test parameter is supplied from the signal generation device 5c through the signal line 13 to the plural semiconductor integrated circuits 8. Then, the operation current when the plural semiconductor integrated circuits are thus operated is measured by the current measurement device 3, and the measured current value is transferred as a control signal 31a to the semiconductor integrated circuit block operation control device 30.

Next, both of the control signals 32a and 32b are similarly set to the logic value “1”, i.e., the respective function circuit blocks 8a and 8b in the semiconductor integrated circuit 8 are put in their operating states, and an operation signal which makes the plural semiconductor integrated circuits 8 as burn-in test targets on the wafer operate at an operation frequency b which is lower than the operation frequency A as the test parameter and is different from the operation frequency a is supplied from the signal generation device 5c through the signal line 13 to the plural semiconductor integrated circuits 8. Then, the operation current when the plural semiconductor integrated circuits are thus operated is measured by the current measurement device 3, and the measured current is transferred as a control signal 31b to the semiconductor integrated circuit block operation control device 30.

The semiconductor integrated circuit block operation control device 30 obtains the power supply current characteristics of the plural semiconductor integrated circuits as burn-in test targets from the two current values 31a and 31b transferred from the current measurement device 3 and the values of the operation frequencies a and b, and calculates an operation current value to be obtained when the plural semiconductor integrated circuits as burn-in test targets are operated with the operation frequency A as the test parameter, on the basis of the obtained power supply current characteristics.

When the obtained power supply current characteristics are such that the calculated operation current value (operation current D) does not exceed the allowable current C of the power supply device 2 as shown by dotted lines in FIG. 6, the semiconductor integrated circuit block operation control device 30 controls the signal generation device 5c with the control signal 33 so as to maintain the state where both of the control signals 32a and 32b of the semiconductor integrated circuit block operation control signal 32 outputted from the signal generation device 5c are the logic value “1”, thereby to put both of the function circuits blocks 8a and 8b in the semiconductor integrated circuit 8 in their operating states, and further, the operation signal which makes the plural test target semiconductor integrated circuits operate at the operation frequency A as the test parameter is supplied from the signal generation device 5c through the signal line 13 to the plural test target semiconductor integrated circuits, thereby executing the burn-in test.

On the other hand, when the obtained power supply current characteristics are such that the calculated operation current value (white dot in FIG. 6) exceeds the allowable current C of the power supply device 2 as shown by a solid line in FIG. 6, the signal generation control device 23 controls the signal generation device 5c with the control signal 25 so as to repeat the state where the control signal 32a and the control signal 32b of the semiconductor integrated circuit block operation control signal 32 outputted from the signal generation device 5c are the logic value “1” and the logic value “0”, respectively, and the state where the control signal 32a is the logic value “0” and the control signal 32b is the logic value “1”, thereby to make the respective function circuit blocks 8a and 8b in the semiconductor integrated circuit 8 operate alternately and time-divisionally, and then the operation signal which makes the plural test target semiconductor integrated circuits operate at the operation frequency A as the test parameter is supplied from the signal generation device 5c through the signal line 13 to the plural test target semiconductor integrated circuits, thereby executing the burn-in test.

The interval of switching the time-division operations of the function circuit blocks 8a and 8b may be appropriately set, for example, it may be every 100 clocks of the operation clocks.

As described above, when the calculated operation current value exceeds the allowable current of the power supply device 2, the respective function circuit blocks 8a and 8b in the semiconductor integrated circuit 8 are operated alternately and time-divisionally to make the semiconductor integrated circuit 8 perform a time-division burn-in operation, and thereby the operation current that flows at one time can be reduced, and thus the operation current is prevented from exceeding the power supply capacity which is allowed by the power supply device 2. Therefore, even when the operation current at the burn-in test is increased due to such as a reduction in the transistor threshold value (Vt) below the standard value, the burn-in test can be reliably carried out with the operation current being limited within the power supply capacity which is allowed by the power supply device 2.

As described above, according to this fourth embodiment, when performing a burn-in test on a plurality of semiconductor integrated circuits mounted on the wafer, each having plural function blocks and being capable of selecting each function block under being operated or under being non-operated, different control signals are given to the plural function blocks in each of the plural semiconductor integrated circuits to time-divisionally operate the plural function blocks. Therefore, the burn-in operation current can be controlled so as to be within the allowable range of the wafer-level burn-in test apparatus, and thus the burn-in test can be executed with reliability.

In the present invention, the way of judging as to whether the plural function circuit blocks should be simultaneously operated or time-divisionally operated is not restricted to that described above. For example, the respective function circuit blocks 8a and 8b may be alternately and time-divisionally operated when a sum of the measured values of two operation currents exceeds the allowable current of the power supply device, which operation currents are the operation current obtained when the semiconductor integrated circuit is operated at the test-parameter operation frequency with only the function circuit blocks 8a being in its operating state, and the operation current obtained when the semiconductor integrated circuit is operated at the test-parameter operation frequency with only the function circuit block 8b being in its operating state.

While in this fourth embodiment the number of the function blocks in the semiconductor integrated circuit is two, the number of the function blocks may be three or more.

### APPLICABILITY IN INDUSTRY

A semiconductor inspection apparatus and a semiconductor integrated circuit of the present invention have the function of controlling an operation power supply current during a wafer-level burn-in test, and are very useful in enhancing the efficiency of the burn-in test and the performance of the burn-in test apparatus, the importance of which is growing along with the progresses in high-density integration and miniaturization of semiconductor integrated circuits.

1. A semiconductor inspection apparatus which performs a burn-in test on a plurality of semiconductor integrated circuits which are mounted on a wafer, wherein
the operation power supply current obtained at the burn-in test can be controlled.

2. A semiconductor inspection apparatus as defined in claim 1, wherein
the operation power supply current at the burn-in test is measured, and the operation power supply current at the burn-in test is controlled based on the measured value.

3. A semiconductor inspection apparatus as defined in claim 1, wherein
the control of the operation power supply current at the burn-in test is performed by controlling the operation frequency of the test target semiconductor integrated circuits in the burn-in test.

4. A semiconductor inspection apparatus as defined in claim 1, wherein
the wafer on which the plural test target semiconductor integrated circuits are mounted is divided into plural test target regions, and the plural test target regions can be time-divisionally operated in the burn-in test.

5. A semiconductor inspection apparatus as defined in claim 4, wherein
each of the plural test target semiconductor integrated circuits is operated with each of plural operation frequencies lower than a predetermined operation frequency, to obtain respective power supply current characteristics of the respective semiconductor integrated circuits from the measured plural current values; and
the operation current values of the plural test target semiconductor integrated circuits at the predetermined operation frequency are calculated based on the obtained respective power supply current characteristics, thereby to time-divisionally operate the plural test target regions when the total of the calculated current values is equal to or larger than a predetermined value.

6. A semiconductor inspection apparatus as defined in claim 4, wherein
the plural test target regions are time-divisionally operated while controlling the presence/absence of the power sources which are supplied to the plural test target regions, respectively.

7. A semiconductor inspection apparatus as defined in claim 4, wherein
the plural test target regions are time-divisionally operated with controlling the presence/absence of an operation signal which is supplied to the semiconductor integrated circuits, respectively, in the plural test target regions.

8. A semiconductor inspection apparatus which performs a burn-in test on a plurality of semiconductor integrated circuits which are mounted on a wafer, each of said semiconductor integrated circuits having plural function blocks and being capable of selecting each function block under being operated or under being non-operated, wherein
different control signals are applied to said respective function blocks in each of said semiconductor integrated circuits in the burn-in test thereby to time-divisionally operate the plural function blocks.

9. A semiconductor integrated circuit which is subjected to a burn-in test, said semiconductor integrated circuit being one among a plurality of semiconductor integrated circuits mounted on a wafer together while said burn-in test is performed, wherein mutually different control signals are applied to respective function blocks possessed by each of said plural semiconductor integrated circuits to time-divisionally operate said plural function blocks, thereby performing a time-division burn-in operation.

10. A semiconductor inspection apparatus as defined in claim 2, wherein
the control of the operation power supply current at the burn-in test is performed by controlling the operation frequency of the test target semiconductor integrated circuits in the burn-in test.

11. A semiconductor inspection apparatus as defined in claim 2, wherein
the wafer on which the plural test target semiconductor integrated circuits are mounted is divided into plural test target regions, and the plural test target regions can be time-divisionally operated in the burn-in test.

12. A semiconductor inspection apparatus as defined in claim 11, wherein
each of the plural test target semiconductor integrated circuits is operated with each of plural operation frequencies lower than a predetermined operation frequency, to obtain respective power supply current characteristics of the respective semiconductor integrated circuits from the measured plural current values; and
the operation current values of the plural test target semiconductor integrated circuits at the predetermined operation frequency are calculated based on the obtained respective power supply current characteristics, thereby to time-divisionally operate the plural test target regions when the total of the calculated current values is equal to or larger than a predetermined value.

13. A semiconductor inspection apparatus as defined in claim 11, wherein
the plural test target regions are time-divisionally operated while controlling the presence/absence of the power sources which are supplied to the plural test target regions, respectively.

14. A semiconductor inspection apparatus as defined in claim 5, wherein
the plural test target regions are time-divisionally operated while controlling the presence/absence of the power sources which are supplied to the plural test target regions, respectively.

15. A semiconductor inspection apparatus as defined in claim 12, wherein
the plural test target regions are time-divisionally operated while controlling the presence/absence of the power sources which are supplied to the plural test target regions, respectively.

16. A semiconductor inspection apparatus as defined in claim 11, wherein
the plural test target regions are time-divisionally operated with controlling the presence/absence of an operation signal which is supplied to the semiconductor integrated circuits, respectively, in the plural test target regions.

17. A semiconductor inspection apparatus as defined in claim 5, wherein
the plural test target regions are time-divisionally operated with controlling the presence/absence of an operation signal which is supplied to the semiconductor integrated circuits, respectively, in the plural test target regions.

18. A semiconductor inspection apparatus as defined in claim 12, wherein
the plural test target regions are time-divisionally operated with controlling the presence/absence of an operation signal which is supplied to the semiconductor integrated circuits, respectively, in the plural test target regions.
